(19) United States
(12) Patent Application Publication
(10) Pub. No.: US 2012/0056280 A1
(43) Pub. Date: Mar. 8, 2012

(54) MEMS Sensor Package

(76) Inventors: Ming-Ching WU, Taipei County (TW); Chih-Kung Huang, Taipei County (TW)

(21) Appl. No.: 12/910,394

(22) Filed: Oct. 22, 2010

(30) Foreign Application Priority Data
Sep. 3, 2010 (TW) 99129897

(51) Int. Cl. H01L 29/84

(52) U.S. Cl. 257/415; 257/E29.324

(57) ABSTRACT

A MEMS sensor package includes a support and a MEMS sensor chip having a mounting side adhered on the support by a point-shaped adhesive or a linear-shaped adhesive in such a way that the MEMS sensor chip has a free side opposite to the mounting and suspended above the support. Because the MEMS sensor chip has the free side that is not restrained on the support, the stress due to deformation of the support will not affect the accuracy of the MEMS sensor chip.

### BACKGROUND OF THE INVENTION

1. Field of the Invention

The present invention relates generally to a sensor package of a micro-electro-mechanical system (hereinafter referred to as “MEMS”) and more particularly, to a MEMS sensor package having a MEMS sensor chip adhered on a support by a point-shaped adhesive or a linear-shaped adhesive in such a way that the MEMS sensor chip has a free side suspended above the support.

2. Description of the Related Art

In a conventional integrated circuit (hereinafter referred to as “IC”) chip package, the bottom of the IC chip is entirely adhered on a support, such as a lead frame or a printed circuit board, by adhesive in order to firmly and stably support the IC chip. As for a MEMS sensor chip package including a MEMS sensor chip having a moveable sensing element, a part of the bottom of the MEMS sensor chip, which corresponds in location to the moveable sensing element, is suspended above a support on which the MEMS sensor chip is adhered. Taking a conventional piezo-resistive three-axis accelerometer shown in FIGS. 1-2 for example, the sensor chip 1 is adhered on a support 3 through adhesives 2 disposed at four corners of a bottom surface of a frame 5 of the sensor chip 1, such that the moveable sensing element 4 of the sensor chip 1 is suspended above the support 3. In this way, the moveable sensing element 4 is moveable relative to the frame 5 of the sensor chip 1 when the moveable sensing element 4 receives an external force. Specifically speaking, the moveable sensing element 4 is indirectly connected with the frame 5 through four flexible bridges 6 on which a plurality of resistances 7 are arranged. Since the movement of the moveable sensing element 4 can cause stress-strain to the bridges 6, which results in change of resistance values of the resistances 7, the change of the external force can be indirectly detected by means of detecting the value changes of the resistances representing the stress-strain variation. It is to be mentioned that the detailed structure and operation principle of the aforesaid conventional accelerometer are well disclosed in prior arts including but not limited to U.S. Pat. No. 4,905,523.

In the above-mentioned MEMS sensor package, in a case the support 3 expends or contracts in dimension in response to change of the ambient or working temperature, because the sensor chip 1 is restrained on the support 3, the deformation stress of the support 3 will distribute to the sensor chip 1 and then affect values of the resistances 7 to further cause a measurement error of the sensor chip 1. In order to resolve this problem, adhesive materials having specific viscosity and temperature resistance for absorbing the deformation stress of the support are developed. However, these specific adhesive materials have a limited effect and usually have a deterioration problem after long-term use.

### SUMMARY OF THE INVENTION

The present invention has been accomplished in view of the above-noted circumstances. It is therefore an object of the present invention to provide a MEMS sensor package, which can prevent the measurement error of the MEMS sensor chip due to deformation of the support.

It is another object of the present invention to provide a MEMS sensor package, which needs not to use an adhesive material having a specific viscosity and a temperature resistance between the MEMS sensor chip and the support.

To attain the above-mentioned objects, the MEMS sensor package provided by the present invention comprises a support and a MEMS sensor chip. The MEMS sensor chip is adhered on the support in such a way that the MEMS sensor chip has a free side suspended above the support. Because the MEMS sensor chip has the free side that is not restrained on the support adhesively or mechanically, the measurement accuracy of the MEMS sensor chip will not be affected by deformation of the support, thereby avoiding the measurement error due to the deformation of the support. For this reason, a general adhesive can be used for adhering the MEMS sensor chip on the support. In other words, it is not necessary to use an adhesive material having a specific range of viscosity and/or a specific temperature resistance to absorb the deformation stress of the support.

In a preferred embodiment of the present invention, the MEMS sensor chip is provided with a mounting side, which is opposite to the free side and adhered on the support by at least one point-shaped adhesive. Preferably, the mounting side of the MEMS sensor chip is adhered on the support by, but not limited to, two point-shaped adhesives provided respectively at two corners of the mounting side. In an alternate form of the MEMS sensor package of the present invention, the mounting side of the MEMS sensor chip is adhered on the support by a linear-shaped adhesive.

For the MEMS sensor chip, any suitable MEMS sensor chip including but not limited to a piezo-resistive or capacity type acceleration sensing chip can be used in the present invention. For example, in a preferred embodiment of the present invention, the MEMS sensor chip is realized by a three-axis acceleration sensing chip of piezo-resistive type, which comprises a frame having the free side, a plurality of flexible bridges extending from the frame towards a center of the frame, and a moveable sensing element, which is so-called “proof mass” and connected with the bridges in such a way that the moveable sensing element is moveably suspended inside the frame. In practice, the MEMS sensor chip adapted to be used in the present invention is not limited to an acceleration sensing chip. Any MEMS sensor chip having a moveable sensing element or a part of the bottom thereof to be suspended above a support on which the MEMS sensor chip is adhered can be used in the present invention.

In the above-mentioned MEMS sensor chip package of the present invention, the support can be, but not limited to, a printed circuit board. For example, in a preferred embodiment of the present invention, the support is realized by an application-specific integrated circuit (hereinafter referred to as “ASIC”) chip for signal processing. The ASIC chip served as the support is electrically connected with the MEMS sensor chip and provided with a bottom side that is bonded on a printed circuit board.

In another preferred embodiment, the support is realized by a printed circuit board and an ASIC chip is bonded on the MEMS sensor chip in a way that the free side of the MEMS sensor chip is suspended between the support and the ASIC chip. In addition, a spacer is supported between the support and the ASIC chip so as to enhancing the structural strength of the package.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWING

The present invention will become more fully understood from the detailed description given herein below and the accompanying drawings which are given by way of illustration only, and thus are not limitative of the present invention, and wherein:

FIG. 1 is a schematic side view of a MEMS sensor package according to a prior art;

FIG. 2 is a top view of the MEMS sensor package shown in FIG. 1, wherein the bonding wires are removed for concise illustration;

FIG. 3 is schematic side view of a MEMS sensor package according to a first preferred embodiment of the present invention;

FIG. 4 is a top view of the MEMS sensor package shown in FIG. 3, wherein the bonding wires are removed for concise illustration;

FIG. 5 is a sectional view taken along line 5-5 of FIG. 4;

FIG. 6 is a schematic top view showing that the MEMS sensor chip is adhered on the support by a point-shaped adhesive;

FIG. 7 is a schematic top view showing that the MEMS sensor chip is adhered on the support by a linear-shaped adhesive;

FIG. 8 is a schematic side view of a MEMS sensor package according to a second preferred embodiment of the present invention; and

FIG. 9 is a schematic side view of a MEMS sensor package according to a third preferred embodiment of the present invention.

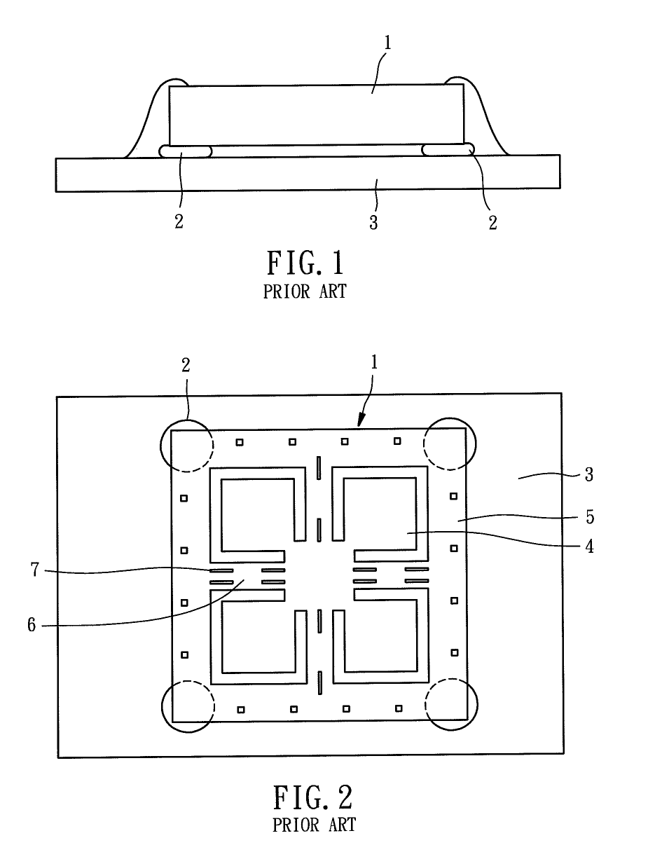

### DETAILED DESCRIPTION OF THE INVENTION

It is to be firstly mentioned that the same numeral references used in the following paragraphs and the drawings refer to the same or similar elements and/or structural features.

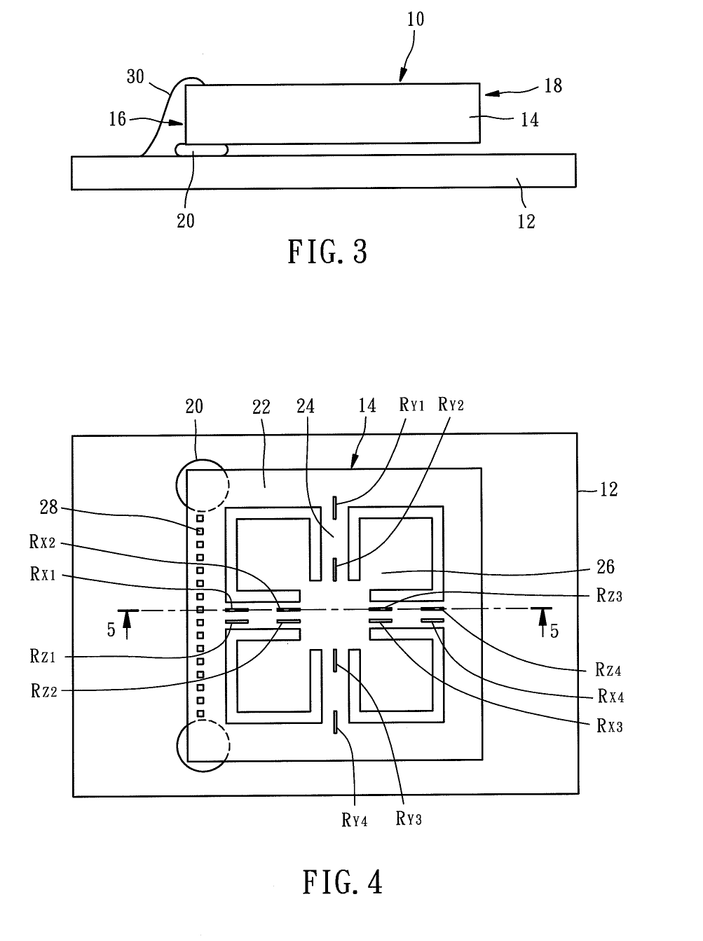

According to a first preferred embodiment of the present invention, a MEMS sensor package, denoted by numeral reference 10, mainly comprises a support 12 and a MEMS sensor chip 14, as shown in FIGS. 3-5.

The support 12 is adapted to mechanically support and electrically connect the MEMS sensor chip 14. In this preferred embodiment, a printed circuit board, which is provided at a surface thereof with a circuit pattern (not shown) for electrical connection with the MEMS sensor chip 14, is used as the support 12.

The MEMS sensor ship 14 has a first side 16 and a second side 18 opposite to the first side 16. Each of two corners at a bottom side of the first side 16 of the MEMS sensor chip 14 is adhered on a top surface of the support 12 by a point-shaped adhesive 20 in such a way that the first side 16 becomes a mounting side connected and restrained on the support 12 and the second side 18 forms a free side that is not restrained on the support 12 but suspended above the support 12. It will be appreciated that the term “free side” used in this written description and the appendix claims means a side that is not connected with the support 12 adhesively and/or mechanically, such that the side is free to move without being restrained by the support 12.

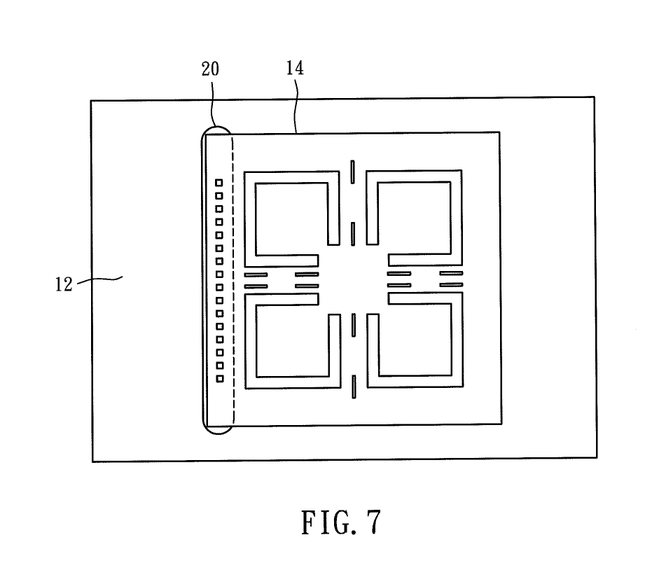

In this preferred embodiment, forming the second side 18 into the free side is realized by a way of using two point-shaped adhesives 20 to connect the MEMS sensor chip 14 with the support 12. This way is however an example only, not a limitation. For example, the mounting side 16 of the MEMS sensor chip 14 can be adhered at a middle thereof on the support 12 by only one point-shaped adhesive 20 as shown in FIG. 6. Alternatively, the mounting side 16 of the MEMS sensor chip 14 can be adhered on the support 12 by a linear-shaped adhesive 20 as shown in FIG. 7. By any of aforesaid ways, the purpose of forming the free side at the MEMS sensor chip 14 can be achieved.

For the adhesive 20 adapted for adhering the MEMS sensor chip 14 on the support 12, a conventional adhesive, including but not limited to an epoxy-based or polyimide-based adhesive, can be used.

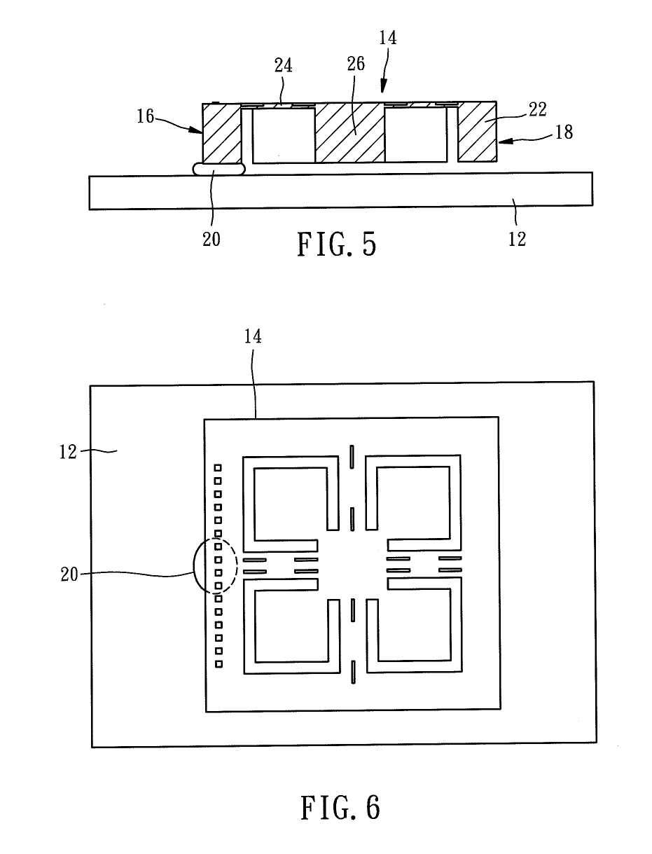

Referring to FIGS. 4-5 again, in this preferred embodiment the MEMS sensor chips 14 is a three-axis acceleration sensing chip of piezo-resistive type, which has a rectangular frame 22, four flexible bridges 24 each extending from a middle of one side of the frame 22 towards a center of the frame 22, and a moveable sensing element 26, which is so-called “proof mass.” The moveable sensing element 26 is connected with the four bridges 24 such that the moveable sensing element 26 is suspended inside the frame 22 and moveable relative to the frame 22 when the moveable sensing element 26 receives an external force. On the top surfaces of the bridges 24, three sets of resistances, i.e. resistances R_{X1} to R_{X4}, resistances R_{Y1} to R_{Y4} and resistances R_{Z1} to R_{Z4}, are arranged. Since the structure and operation principle of the accelerometer of this kind are well-known to a person skilled in the arts including but not limited to U.S. Pat. No. 4,905,523, a detailed description thereof needs not to be recited hereinafter.

In addition, a plurality of bonding pads 28 for signal input/output are arranged on a top surface of the mounting side 16. By means of bonding wires 30 respectively connecting the bonding pads 28 with the support 12, the MEMS sensor chip 14 is electrically connected with the support 12. However, it will be appreciated that the way of electrically connecting the MEMS sensor chip 14 to the support 12 is not limited to wire bonding technology. Any suitable way, including but not limited to flip chip technology, can be used.

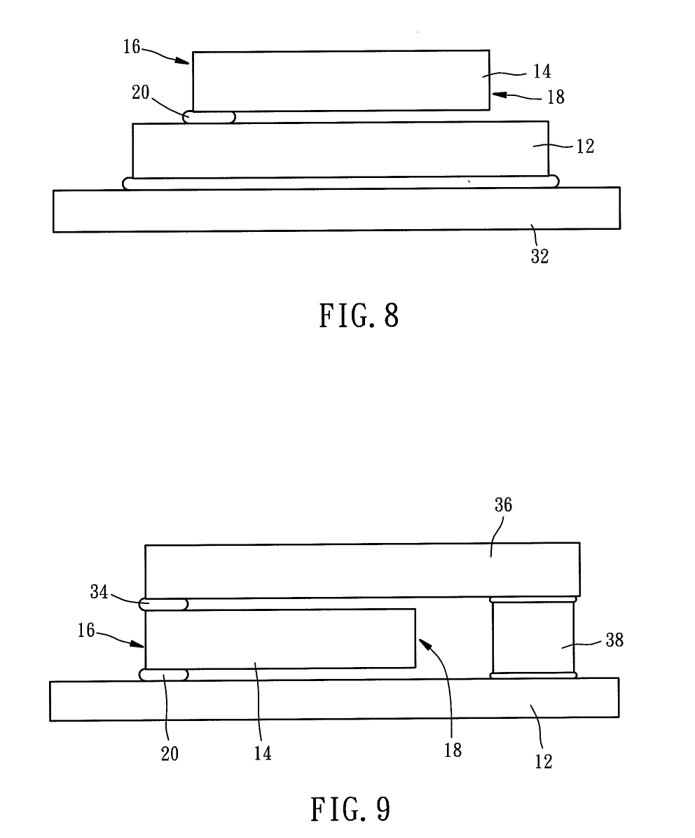

In the above-mentioned preferred embodiment, the support 12 is realized by a printed circuit board. However, the support 12 can be other forms according to the actual need. For example, FIG. 8 shows a MEMS sensor package according to a second preferred embodiment of the present invention, in which the support 12 is realized by an ASIC chip. As shown in FIG. 8, the mounting side 16 of the MEMS sensor chip 14 is adhered on a top surface of the ASIC chip such that a free side 18 is formed and suspended above the ASIC chip, i.e. the support 12. In addition, the bottom side of the ASIC chip is bonded on a printed circuit board 32. The electrical connection between the MEMS sensor chip and the ASIC chip or between the ASIC chip and the printed circuit board can be achieved by bonding wires (not shown) or any suitable way.

FIG. 9 shows a MEMS sensor package according to a third preferred embodiment of the present invention. In this embodiment, the support 12 for supporting the MEMS sensor chip 14 is a printed circuit board. An ASIC chip 36 is adhered on a top surface of the mounting side 16 of the MEMS sensor chip 14 by a point-shaped adhesive or a linear-shaped adhesive, such that the free side 18 of the MEMS sensor ship 14 is suspended between the support 12 and the ASIC chip 36. To enhance the structural strength of the package and to enable the free side 18 of the MEMS sensor ship 14 to be stably suspended between the support 12 and the ASIC chip 36, a spacer 38 is adhesively supported between the support 12 and the ASIC chip 36. For the electrical connection between the MEMS sensor chip 14 and the ASIC chip 36 or between the MEMS sensor chip 14 and the support 12, bonding wires (not shown) or any suitable way can be used.

In conclusion, the MEMS sensor package of the present invention is characterized in that the four sides of the bottom surface of the MEMS sensor chip are not totally adhered and restrained on the support, but only one side, i.e. the mounting side, is adhered on the support. Since the MEMS sensor chip has a free side that is not restrained on the support, the accuracy of the MEMS sensor chip will not be affected by the deformation of the support. As a result, a general adhesive, which needs not to have a specific range of viscosity and/or a specific temperature resistance, can be used to adhere the MEMS sensor chip on the support.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A MEMS sensor package, comprising:
a support; and
a MEMS sensor chip adhered on the support and having a free side suspended above the support.

2. The MEMS sensor package as claimed in claim 1, wherein the MEMS sensor chip has a mounting side opposite to the free side and adhered on the support by at least one point-shaped adhesive.

3. The MEMS sensor package as claimed in claim 2, wherein the mounting side of the MEMS sensor chip has two corners, each of which is adhered on the support by one said point-shaped adhesive.

4. The MEMS sensor package as claimed in claim 3, further comprising:
an ASIC chip bonded on the MEMS sensor chip in a way that the free side of the MEMS sensor chip is suspended between the support and the ASIC chip; and
a spacer supported between the support and the ASIC chip.

5. The MEMS sensor package as claimed in claim 3, wherein the support is an ASIC chip having a bottom side bonded on a printed circuit board.

6. The MEMS sensor package as claimed in claim 1, wherein the MEMS sensor chip has a mounting side opposite to the free side and adhered on the support by a linear-shaped adhesive.

7. The MEMS sensor package as claimed in claim 6, further comprising:
an ASIC chip bonded on the MEMS sensor chip in a way that the free side of the MEMS sensor chip is suspended between the support and the ASIC chip; and
a spacer supported between the support and the ASIC chip.

8. The MEMS sensor package as claimed in claim 6, wherein the support is an ASIC chip having a bottom side bonded on a printed circuit board.

9. The MEMS sensor package as claimed in claim 1, wherein the MEMS sensor chip comprises a frame having the free side, a plurality of flexible bridges extending from the frame towards a center of the frame, and a moveable sensing element connected with the flexible bridges such that the moveable sensing element is suspended inside the frame.

10. The MEMS sensor package as claimed in claim 9, wherein the frame of the MEMS sensor chip has a mounting side opposite to the free side and adhered on the support by at least one point-shaped adhesive.

11. The MEMS sensor package as claimed in claim 10, wherein the mounting side of the frame of the MEMS sensor chip has two corners, each of which is adhered on the support by one said point-shaped adhesive.

12. The MEMS sensor package as claimed in claim 11, further comprising:
an ASIC chip bonded on the MEMS sensor chip in a way that the free side of the MEMS sensor chip is suspended between the support and the ASIC chip; and
a spacer supported between the support and the ASIC chip.

13. The MEMS sensor package as claimed in claim 11, wherein the support is an ASIC chip having a bottom side bonded on a printed circuit board.

14. The MEMS sensor package as claimed in claim 9, wherein the frame of the MEMS sensor chip has a mounting side opposite to the free side and adhered on the support by a linear-shaped adhesive.

15. The MEMS sensor package as claimed in claim 14, further comprising:
an ASIC chip bonded on the MEMS sensor chip in a way that the free side of the MEMS sensor chip is suspended between the support and the ASIC chip; and
a spacer supported between the support and the ASIC chip.

16. The MEMS sensor package as claimed in claim 14, wherein the support is an ASIC chip having a bottom side bonded on a printed circuit board.

17. The MEMS sensor package as claimed in claim 1, wherein the support is a printed circuit board.

18. The MEMS sensor package as claimed in claim 17, further comprising:
an ASIC chip bonded on the MEMS sensor chip in a way that the free side of the MEMS sensor chip is suspended between the printed circuit board and the ASIC chip; and
a spacer supported between the printed circuit board and the ASIC chip.

19. The MEMS sensor package as claimed in claim 1, wherein the support is an ASIC chip having a bottom side bonded on a printed circuit board.
